(19) United States
(12) Patent Application Publication
(10) Pub. No.: US 2010/0073577 A1
(43) Pub. Date: Mar. 25, 2010

(54) PORTABLE DIGITAL ANTENNA

(75) Inventors: Alexander J. Soo, Irvine, CA (US); Steven J. Davis, Hermosa Beach, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: PowerQ Technologies, Inc., Irvine, CA (US)

(21) Appl. No.: 12/561,901

(22) Filed: Sep. 17, 2009

Related U.S. Application Data
(60) Provisional application No. 61/098,108, filed on Sep. 18, 2008.

(51) Int. Cl. H04N 5/50; H01Q 1/42; H01Q 9/06; H01Q 1/08; H03J 5/00

(52) U.S. Cl. 348/731; 343/872; 343/843; 343/881; 334/39; 348/E05.097

(57) ABSTRACT

A lightweight and compact design provides for a portable antenna device that is able to receive over the air digital broadcasts. Such a device can receive a large number of high definition digital signals, over a wide spectrum. The device can be powered by a number of approaches, including receiving power over a USB or similar connection. Such a device thus can be used with home analog or digital televisions as well as portable digital media devices. The device includes an extendable, substantially rectangular antenna element that is shaped to receive the digital signals over a wide band.

### CROSS-REFERENCES TO RELATED APPLICATIONS

This application claims the benefit of U.S. Provisional Patent Application No. 61/098,108, entitled PORTABLE DIGITAL ANTENNA, filed Sep. 18, 2008, which is hereby incorporated herein by reference.

### BACKGROUND OF THE INVENTION

As analog television broadcast signals are slowly being phased out around the world, there is a need for many over-the-air (OTA) broadcast viewers to convert to digital broadcast equipment. In many instances, this will involve purchasing a digital tuner that can receive digital broadcasts and convert the broadcast signal to be viewed on an analog television or other such viewing device. The user in many cases will still have to utilize an antenna to receive OTA broadcasts, and standard analog antennas such as telescoping antennas are not typically able to receive broadcasts over a sufficiently wide range of frequencies.

Also, an increasing number of people are viewing OTA broadcasts on mobile devices such as laptops, portable media players, handheld televisions, and other such devices. Even when these devices are capable of receiving digital broadcasts, the antennas provided are generally not very powerful or able to receive signals over a wide frequency range. Further, since digital is more of an “all or nothing” type of signal, it is more important to have a good antenna in order to receive any displayable signal at all.

### BRIEF DESCRIPTION OF THE DRAWINGS

Various embodiments in accordance with the present disclosure will be described with reference to the drawings, in which:

FIG. 1 illustrates an environment in which aspects of the various embodiments can be implemented;

FIGS. 2(a)-(c) illustrate different views of an antenna device in accordance with one embodiment;

FIG. 3 illustrates antenna designs that can be used in accordance with various embodiments;

FIGS. 4(a)-(d) illustrate different views of an aesthetically-pleasing case design that can be used in accordance with various embodiments, with FIG. 4(d) illustrating example components that can be utilized inside such a case;

FIG. 5 illustrates a design for an antenna element that can be used in accordance with various embodiments;

FIG. 6 illustrates an example impedance curve at different frequencies for an antenna element device in accordance with various embodiments;

FIG. 7 illustrates an example input impedance curve for an antenna element that can be used in accordance with various embodiments; and

FIG. 8 illustrates an example gain curve for an antenna element that can be used in accordance with various embodiments.

### DETAILED DESCRIPTION OF THE INVENTION

Systems and methods in accordance with various embodiments provide for a portable wideband antenna device, such as may be configured to receive high definition (“HD”) and/or standard definition (“SD”) OTA broadcast television signals. A device in accordance with one embodiment includes a lightweight and portable device comprising an antenna element, a compact enclosure, and associated electronics.

Current high definition television (“HDTV”) antennas on the market are quite large and bulky, not lending themselves to portable applications. Many of these antennas are oriented for home use only, and consist of a combination of log-periodic, patch, or Yagi type antennas. Due to the physical size of these antennas, they are not suitable for portable applications.

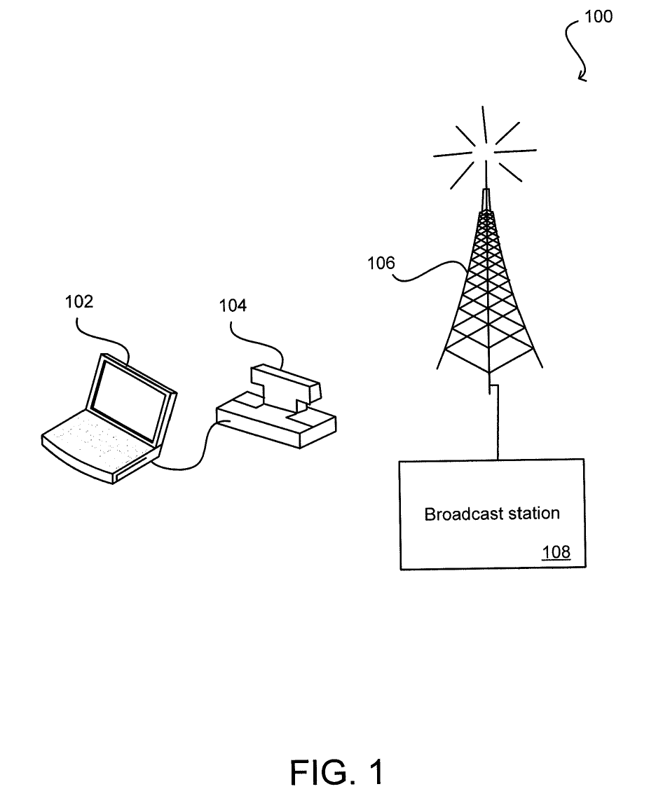

Devices in accordance with various embodiments provide a compact antenna solution for portable applications. FIG. 1 illustrates an example environment 100 wherein a user can take advantage of such a device. In this example, a user with a laptop computer 102 or other such portable viewing device interfaces a portable antenna device 104 to the laptop computer, such as by using a standard USB or other appropriate connection, wherein the laptop includes an HDTV receiver card or other such component. In other embodiments, a separate receiver or tuner can be used that is external to the laptop, or can be included within the portable antenna device. The antenna device 104 is able to receive signals broadcast from a broadcasting tower 106 or similar device used to send television or other media signals from a broadcasting station 108 or other such provider. The small physical size of the antenna device 104, such as a device that is less than about seven inches in length, less than about two inches in width, and less than about one and a half inch in thickness, allows for convenient transport, such as in the user's laptop case. Further, forming the casing out of a lightweight material such as a lightweight plastic, plastic composite, or polymer composite allows the device to be conveniently carried in such an over the shoulder or similar case, etc.

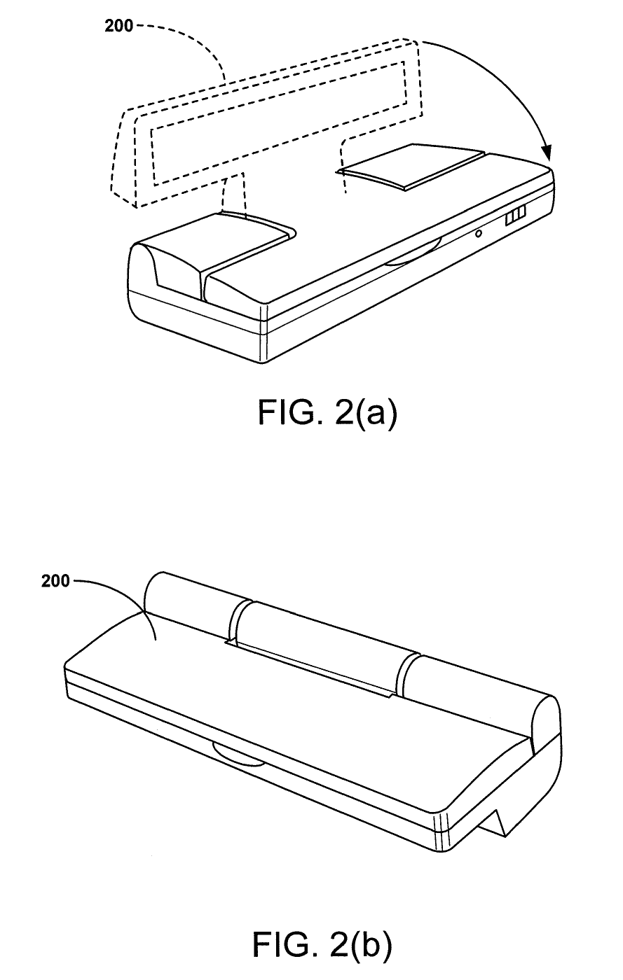

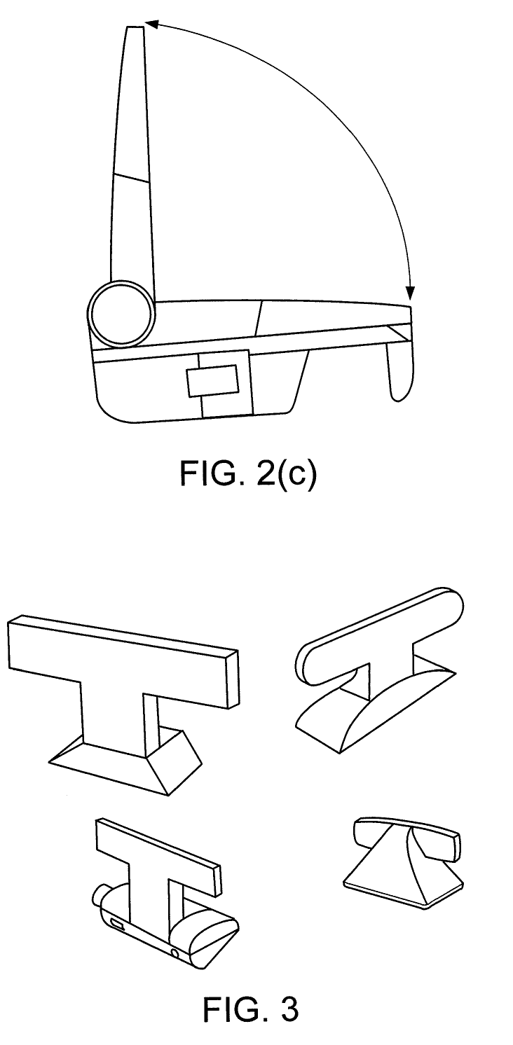

An antenna device in accordance with various embodiments includes a collapsible, rotatable, or folding antenna element 200, such as is shown in FIGS. 2(a) and 2(b). The antenna element pivots about a hinge or other such attachment, such as can be seen in FIG. 2(c). The antenna element can provide maximum reception capability when fully extended, in one embodiment being substantially perpendicular to the non-extended portion of the casing, and can provide maximum compactness when fully closed. As seen in FIG. 2(b), the antenna element can be substantially flush with the case when the antenna is closed. The device can include a damped motion system spring loader which, when a release button on the casing is pressed, causes the antenna comes up relatively slowly and with a controlled motion. The casing for the antenna element can take any of a number of appropriate shapes, such as are illustrated in FIG. 3.

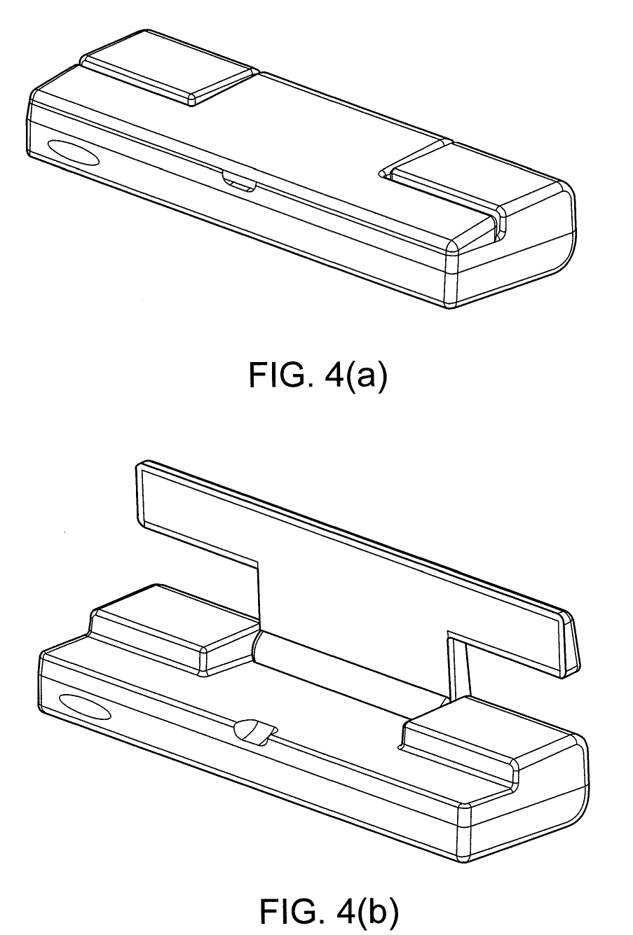

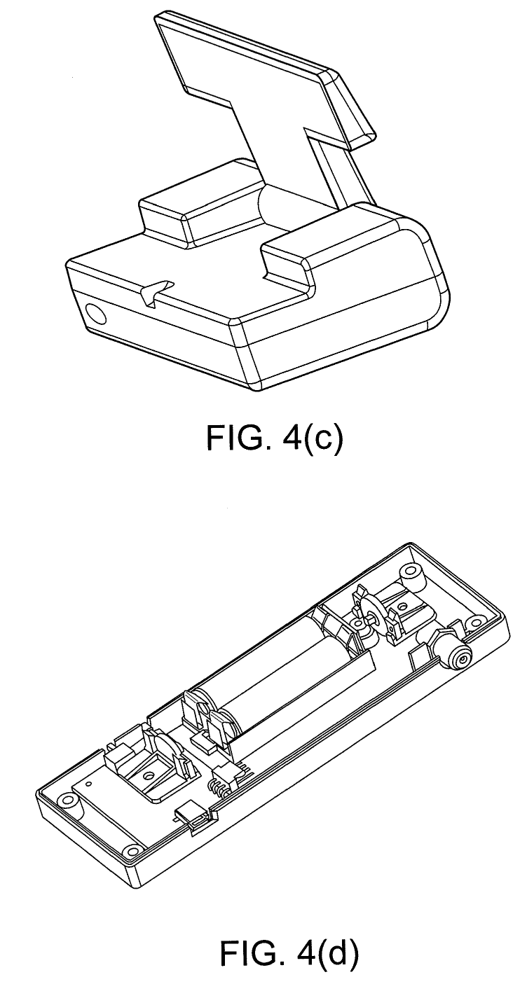

Additionally, the small physical size and modern shape is aesthetically more pleasing and less obtrusive than other antennas on the market. FIGS. 4(a)-(c) illustrate aesthetically pleasing casing options that can be used with various embodiments. The look, shape, and performance of these devices also make them suitable for home use as well. A portable device can be utilized in the home to receive OTA free HD and SD television programs, in many cases negating the requirement for consumers to pay for monthly cable service. The portability also allows viewers to carry the antenna to different televisions, negating the need to buy a specific standalone antenna for each television or other such viewing device. The casing can include a power light on the front that indicates when the device is active. In some embodiments, the device includes a power on/off switch, while other embodiments might receive power and be active any time the device is connected (such as by a USB connection) to a display device or other such component.

An antenna device in accordance with one embodiment includes a low noise amplifier used to increase the signal received, thus attaining better reception. In one device, a 50 ohm matched transformer is used, while other devices can use a 75 ohm transformer or other appropriate element.

Antenna devices in accordance with various embodiment can be powered by any of a variety of sources. A provision for powering the devices via replaceable batteries, via USB power, or via an AC/DC adapter, for example, can be provided. For example, FIG. 4(d) shows storage for batteries, as well as a USB connector, along with appropriate components. FIG. 4(d) also shows a standard coaxial port that can be used to connect the device to an analog television or similar device.

An antenna device in accordance with various embodiments also can include a digital tuner, HDTV tuner, MPEG decoder, and/or other electronics useful for receiving signals and interfacing with a personal computer, laptop, or directly to a television set, for example, to allow a user to view the OTA programming without need for an additional device or built-in tuner in the viewing device. Interfaces can include, for example, USB, FireWire, HDMI, component video, composite, or any other appropriate connector known or used in the art.

In another embodiment, such an integrated device can be interfaced to other portable devices to provide digital television program viewing. One application would interface with a portable device such as a portable media player (e.g., an iPod), a personal data assistant, or a cellular phone or smart phone (e.g., an iPhone, Palm Treo, or Blackberry) to enable program viewing and/or recording. The antenna device can function as a docking device and essentially convert the docked device into a Digital Video Recorder which could use the calendar and other built-in applications on the docked device (e.g. iPhone) to add/delete programming schedules, and perform other such functions.

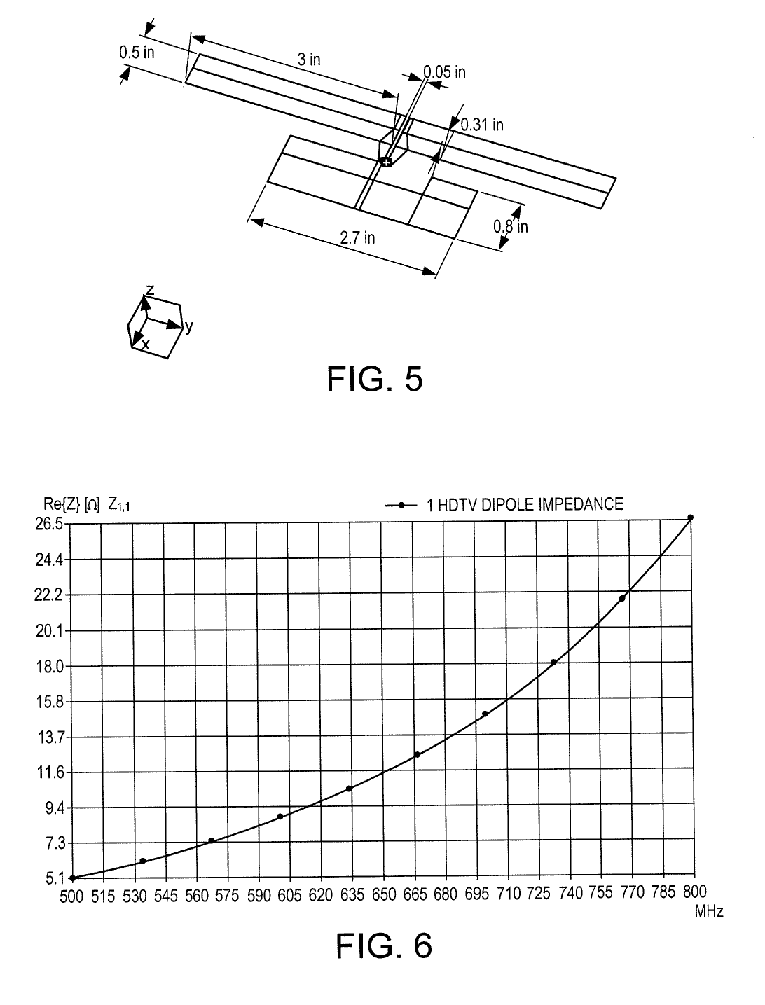

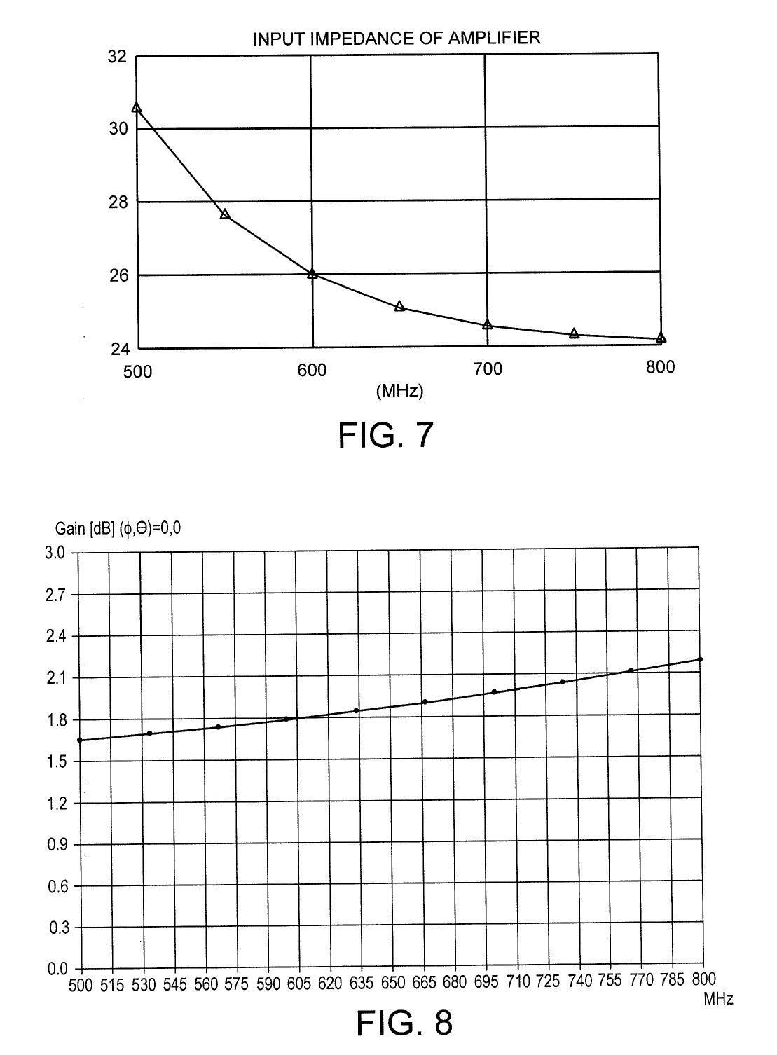

The antenna device is able to provide better results than many larger existing antennas through the design of the antenna element. FIG. 5 illustrates an example of the antenna element without the casing, illustrating dimensions that can be used in one embodiment. The antenna element can be made of any appropriate material, such as solid copper, copper over dielectric, or gold over dielectric. In some devices, strips of plastic or another such material can be used to sandwich the antenna element. As seen, an active portion of the antenna in this example is on the order of about six inches in length and about a half inch in width. The antenna element in one embodiment is about 0.062 inches in thickness, while other thicknesses less than about 0.1 inches are used in other embodiments, and still other thicknesses are possible. As can be seen, the antenna element is not a linear dipole or similar element, but a rectangular element. While the length can be selected to provide the frequencies at which the device will receive signals, the width can be selected to provide the bandwidth. In this example, the antenna impedance is about 20 ohms which matches the amplifier input impedance (matched for better power transfer). The impedance for different frequencies for an example antenna device is illustrated in FIG. 6. Conventionally people use 50 ohm impedances, even though other impedances may be better suited as in this case. FIG. 7 shows an example of a gain curve for input impedance in accordance with one embodiment.

The antenna gain in one example is around 2 db over the frequency band, such as is illustrated in the example plot of FIG. 8. This is not very directional, which avoids having to carefully adjust the positioning of the antenna as opposed to how others require careful alignment, which is not practical for a consumer. This is especially important as each station might be in a different location.

Such an antenna can enable a user to watch dozens of OTA digital broadcasts, while conventional antennas are lucky to be able to pick up a couple of broadcasts. The antenna element can be specially designing and optimized to match any appropriate broadcast spectrum, such as the current HDTV spectrum, using the smallest possible size. Various genetic algorithms can be used to determine a rough shape and size for such an antenna based on factors such as the desired dimensions, physical constraints, and desired performance of the antenna, and the element can be optimized based on the casing, which can otherwise slightly impact performance.

The frequency and bandwidth thus can be set and matched to the desired spectrum. Most antennas are narrow band, and in general more frequencies come with higher losses. Elements as described herein provide wide bandwidth performance in a small antenna. The rectangular element design provides for performance over a wider bandwidth but in a compact shape. Such approaches have not previously been used advantageously for such purposes.

The specification and drawings are, accordingly, to be regarded in an illustrative rather than a restrictive sense. It will, however, be evident that various modifications and changes may be made thereunto without departing from the broader spirit and scope of the invention as set forth in the claims.

What is claimed is:

1. A device for receiving digital broadcast signals, comprising:
a base portion including components useful in transforming and outputting a received digital broadcast signal; and
an extendable antenna portion, the extendable antenna portion being moveably connected to the base portion and including a substantially rectangular antenna element, the substantially rectangular antenna element having dimensions selected to receive digital broadcast signals over a frequency band of a digital broadcast spectrum.

2. A device according to claim 1, wherein:
the device is portable.

3. A device according to claim 1, wherein:
the device includes a casing made of a lightweight material.

4. A device according to claim 1, wherein:
the device includes at least one connector configured to allow the device to be connected with at least one of a tuner device and a display device operable to utilize a received digital broadcast signal.

5. A device according to claim 1, wherein:
the extendable portion is connected to the base portion by a hinge mechanism.

6. A device according to claim 1, further comprising:
at least one power component able to provide power to the device.

7. A device according to claim 1, wherein:
the device is able to receive power over a connection with an external device.

8. A device according to claim 1, wherein:
the substantially rectangular antenna element has a width selected to receive the frequency band of the digital broadcast spectrum.

9. A device according to claim 1, further comprising:
a tuning component in the base portion operable to select a frequency of the digital broadcast spectrum and output the digital signal at the selected frequency.

10. A system for receiving digital broadcast signals, comprising:
a portable digital antenna device, the portable digital antenna device including:
a base portion including components useful in transforming and outputting a received digital broadcast signal; and
an extendable antenna portion, the extendable antenna portion being moveably connected to the base portion and including a substantially rectangular antenna element, the substantially rectangular antenna element having dimensions selected to receive digital broadcast signals over a frequency band of a digital broadcast spectrum; and
a tuner device operable to select a frequency of the digital broadcast spectrum and output a digital signal from the portable digital antenna device at the selected frequency; and
a display device for displaying an image corresponding to information in the digital signal.

11. A system according to claim 10, wherein:
the portable digital antenna device includes a casing made of a lightweight material.

12. A device according to claim 10, wherein:
the portable digital antenna device includes at least one connector configured to allow the portable digital antenna device to be connected with at least one of the tuner device and the display device.

13. A system according to claim 10, wherein:
the extendable portion is connected to the base portion by a hinge mechanism.

14. A system according to claim 10, further comprising:
at least one power component able to provide power to the portable digital antenna device.

15. A system according to claim 10, wherein:
the portable digital antenna device is able to receive power over a connection with at least one of the tuner device and the display device.

16. A system according to claim 10, wherein:
the substantially rectangular antenna element has a width selected to receive the frequency band of the digital broadcast spectrum.
